(19) United States
(12) Patent Application Publication
(10) Pub. No.: US 2012/0048344 A1
(43) Pub. Date: Mar. 1, 2012

(54) CELL MODULES HAVING AT LEAST TWO ASSEMBLED SOLAR CELLS

(75) Inventors: YEE SHYI CHANG, TAIPEI (TW); YUHAI LIU, TAIPEI (TW); CHI-JEN LIU, TAIPEI (TW)

(73) Assignee: AN CHING NEW ENERGY MACHINERY & EQUIPMENT CO., LTD., TAIPEI (TW)

(21) Appl. No.: 13/017,583

(22) Filed: Jan. 31, 2011

(30) Foreign Application Priority Data
Aug. 25, 2010 (TW) 99128503

(51) Int. Cl. H01L 31/048

(52) U.S. Cl. 136/251

(57) ABSTRACT

A cell module, comprising: a first solar cell, and a second solar cell. Said first solar cell absorbs green light, blue light, and ultraviolet light and converts them into electrical energy; while red light, orange light, yellow light, and infrared light are allowed to pass through said first solar cell. Said second solar cell is located below said first solar cell and is shielded by said first solar cell, and is combined with said first solar cell into said cell module. Said second solar cell absorbs said red light, said orange light, said yellow light, and said infrared light passing through said first solar cell, and converts them into electrical energy.

### BACKGROUND OF THE INVENTION

1. Field of the Invention

The present invention relates to a cell module, and in particular to a cell module having at least two assembled solar cells.

2. The Prior Arts

Among various technologies of alternative energy resources and regenerated energy resources, solar cell is the most promising one and getting most of the attention. The main reasons for this is that, solar cell is capable of converting solar energy directly into electrical energy, and it does not produce detrimental materials such as carbon dioxide or nitride, thus it will not cause pollution to the environment. Among various types of solar cells, the thin film solar cell has the best potential for further development due to its advantages of lower manufacturing cost.

In general, structure of a conventional thin film solar cell has a substrate sequentially stacked thereon with an electrode layer, a photovoltaic layer, and an electrode layer. When light irradiates on a thin film solar cell, atoms in the photovoltaic layer are agitated to produce pairs of free electrons and holes, and through an internal electrical field formed by a PN junction, electrons and holes tend to move toward two electrode layers, thus producing a potential difference for a state of electrical energy storage. Meanwhile, if an external circuit or electronic device is connected, then, the thin film solar cell is able to output electricity to drive the external circuit or electronic device into performing the actions required. However, presently, the performance of the conventional solar cell is still not perfect, it has much room for improvement.

### SUMMARY OF THE INVENTION

In view of the problems and shortcomings of the prior art, the present invention provides a cell module having at least two assembled solar cells, that is capable of providing better photoelectric conversion efficiency and have longer service life.

A major objective of the present invention is to provide a cell module, comprising a first solar cell and a second solar cell. The first solar cell absorbs green light, blue light, and ultraviolet light, and converts them into electrical energy, while red light, orange light, yellow light, and infrared light are transmitted through the first solar cell. The second solar cell is located below the first solar cell and is shielded by the first solar cell, and the first solar cell and the second solar cell are combined into a cell module. The second solar cell absorbs the red light, orange light, yellow light, and infrared light transmitted through the first solar cell and converts them into electrical energy.

In an embodiment of the present invention, the first solar cell is a transparent solar cell.

In another embodiment of the present invention, the second solar cell includes: an organic solar cell, a dye solar cell, a GaAs solar cell, or a CdTe solar cell.

In a yet another embodiment of the present invention, a gap is maintained between the first solar cell and the second solar cell.

In a further embodiment of the present invention, the first solar cell and the second solar cell are placed closely together.

In another embodiment of the present invention, the first solar cell and the second solar cell are connected in series or in parallel.

In a yet another embodiment of the present invention, the cell module further includes a junction box, such that the first solar cell and the second solar cell are electrically connected through the junction box.

In a further embodiment of the present invention, the cell module further includes a housing, so that the first solar cell and the second solar cell are both located in the housing, and the second solar cell is located between a bottom portion of the housing and the first solar cell.

In another embodiment of the present invention, the housing is a transparent housing.

In a yet another embodiment of the present invention, the first solar cell and the second solar cell are both thin film solar cells.

In the present invention, the cell module is formed by placing the first solar cell on the second solar cell, so as to shield the second solar cell. The first solar cell absorbs green light, blue light, and ultraviolet light and allows most of the red light, orange light, yellow light, and infrared light to pass through. As such, in addition to raising the photoelectric conversion efficiency of the entire cell module, it can also reduce the possibility of irradiating ultraviolet light on the second solar cell, hereby prolonging the service life of the second solar cell. In addition, since the first solar cell is placed on the second solar cell, thus preventing the second solar cell from the outside damage, such as hailstone.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a schematic diagram of a cell module according to an embodiment of the present invention; and

FIG. 2 is a schematic diagram of a cell module according to another embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings. And, in the following, various embodiments are described in explaining the technical characteristics of the present invention.

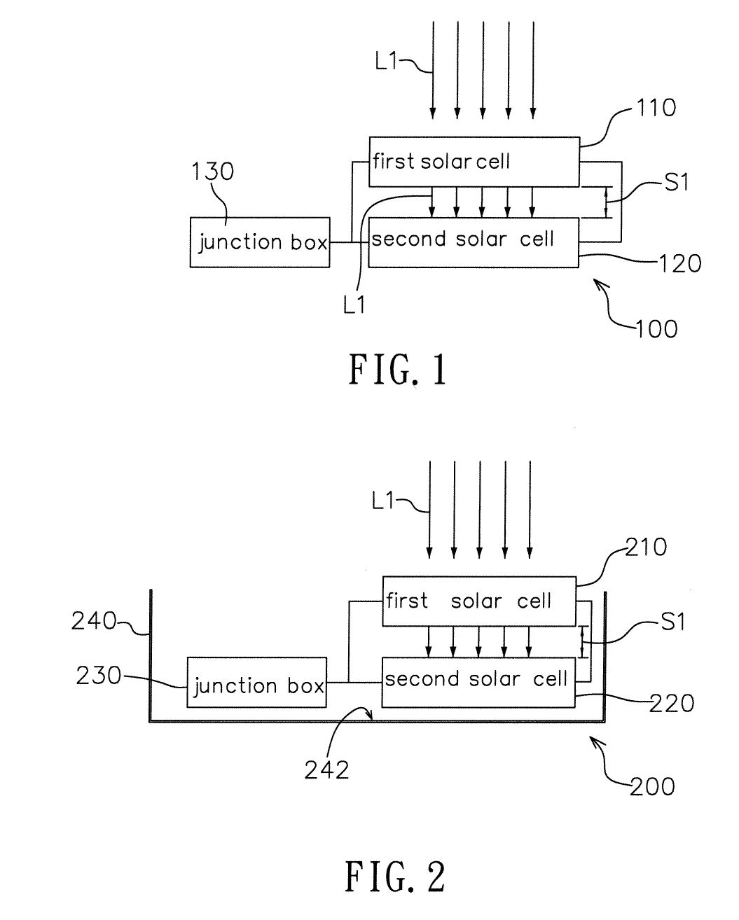

Refer to FIG. 1 for a schematic diagram of a cell module according to an embodiment of the present invention. As shown in FIG. 1, the cell module 100 of the present invention comprises a first solar cell 110 and a second solar cell 120. The first solar cell 110 is apt to absorb green light, blue light, and ultraviolet light in light beam L1, and convert them into electrical energy. In addition, most of the red light, orange light, yellow light, and infrared light will pass through the first solar cell 110 and reach the second solar cell 120. In the present embodiment, the first solar cell 110 is a transparent thin film solar cell, wherein, the technical characteristics of the first solar cell 110 is mainly in absorbing green light, blue light, and ultraviolet light in light beam L1, and converting them into electrical energy.

The second solar cell 120 is located below the first solar cell 110, and is shielded by the first solar cell 110, as shown in FIG. 1. The major technical characteristic of the present embodiment is that, the second solar cell 120 is capable of absorbing most of the red light, orange light, yellow light, and infrared light passing through the first solar cell, and converting them into electrical energy. In the present embodiment, the second solar cell 120 can be an organic solar cell, a dye solar cell, a GaAs solar cell, or a CdTe solar cell. By way of example, since the second solar cell 120 is shielded by the first solar cell 110, and the first solar cell 110 absorbs most of the green light, blue light, and ultraviolet light in light beam L1, thus it can prevent fast shortening of service life of the second solar cell 120 due to irradiated by the ultraviolet light.

To be more specific, since the properties of organic material or dye material is liable to be affected by the irradiation of ultraviolet light, therefore, in case that organic solar cell or dye solar cell is irradiated by the ultraviolet light, its service life will be relatively shortened. In the present embodiment, since the first solar cell 110 can absorb most of the green light, blue light, and ultraviolet light in light beam L1, thus reducing the possibility of the second solar cell 120 being irradiated by ultraviolet light, hereby significantly increasing the service life of the second solar cell 120, and increasing the service life of the entire cell module 100, and its photoelectric conversion efficiency.

In the present embodiment, the cell module 110 further includes a junction box 130, so that the first solar cell 110 and the second solar cell 120 are connected electrically through the junction box 130, as shown in FIG. 1. In addition, the first solar cell 110 and the second solar cell 120 can be connected in series or in parallel depending on actual requirements. By way of example, in case that larger voltage output is required, then the first solar cell 110 and the second solar cell 120 can be connected in series. On the contrary, in case that larger current output is required, then the first solar cell 110 and the second solar cell 120 can be connected in parallel. As shown in FIG. 1, the parallel connection of the first solar cell 110 and the second solar cell 120 is taken as an example, however, the present invention is not limited to this.

Moreover, in addition to making adjustment for the current or voltage converted by the first solar cell 110 and the second solar cell 120 from the light beam L1, for being utilized by the subsequent electronic devices connected to this cell module 100, the junction box 130 also has the function of storing the electric energy thus obtained for future utilization.

In the present embodiment, a gap S1 can be kept between the first solar cell 110 and the second solar cell 120, namely, the first solar cell 110 and the second solar cell 120 are not placed closely together, as shown in FIG. 1. In another embodiment not shown, the first solar cell 110 and the second solar cell 120 are placed closely together. In other words, in a modularized cell module 100, whether the first solar cell 110 and the second solar cell 120 must be placed closely together depends on actual requirements.

Then, refer to FIG. 2 for a schematic diagram of a cell module according to another embodiment of the present invention. As shown in FIG. 2, the cell module 200 includes a first solar cell 210, a second solar cell 220, and a housing 240, such that the first solar cell 210 and the second solar cell 220 are placed in the housing 240, and the second solar cell 220 are located between a bottom portion 242 of housing 240 and the first solar cell 210. In the present embodiment, the housing 240 is a transparent housing, while in other embodiments, the housing can be made of non-transparent material.

Similarly, in cell module 200, the first solar cell 210 is apt to absorb green light, blue light, and ultraviolet light in light beam L1, and convert them into electrical energy. In addition, most of the red light, orange light, yellow light, and infrared light will pass through the first solar cell 210 and reach the second solar cell 120. In the present embodiment, the first solar cell 210 is a transparent thin film solar cell, wherein, the technical characteristics of the first solar cell 210 is mainly in absorbing green light, blue light, and ultraviolet light in light beam L1, and converting them into electrical energy.

The second solar cell 220 is located below the first solar cell 210, and is shielded by the first solar cell 210, as shown in FIG. 2. The major technical characteristic of the present embodiment is that, the second solar cell 220 is capable of absorbing most of the red light, orange light, yellow light, and infrared light passing through the first solar cell, and converting them into electrical energy. In the present embodiment, the second solar cell 220 can be an organic solar cell, a dye solar cell, a GaAs solar cell, or a CdTe solar cell. By way of example, since the second solar cell 220 is shielded by the first solar cell 210, and the first solar cell 210 is able to absorb most of the green light, blue light, and ultraviolet light in light beam L1, thus it can prevent fast shortening of service life of the second solar cell 220 due to irradiated by the ultraviolet light.

Since the properties of organic material or dye material are liable to be affected by the irradiation of ultraviolet light, therefore, in case that organic solar cell or dye solar cell is irradiated by ultraviolet light, its service life will be relatively shortened. In the present embodiment, since the first solar cell 210 can absorb most of the green light, blue light, and ultraviolet light in light beam L1, thus reducing the possibility of the second solar cell 220 being irradiated by ultraviolet light, hereby significantly increasing the service life of the second solar cell 220, and increasing the service life of the entire cell module 100, and its photoelectric conversion efficiency.

In the present embodiment, the cell module 210 further includes a junction box 230, so that the first solar cell 210 and the second solar cell 220 are connected electrically through the junction box 230, as shown in FIG. 2. In addition, the first solar cell 210 and the second solar cell 220 can be connected in series or in parallel depending on actual requirements. By way of example, in case that larger voltage output is required, then the first solar cell 210 and the second solar cell 220 can be connected in series. On the contrary, in case that larger current output is required, then the first solar cell 210 and the second solar cell 220 can be connected in parallel. As shown in FIG. 2, the parallel connection of the first solar cell 210 and the second solar cell 220 is taken as an example, however, the present invention is not limited to this. It has to be mentioned that, the junction box 230 can be located in the housing 240 as shown in FIG. 2, in another embodiment not shown, the junction box 230 can also be located outside the housing 240, and connected electrically to the first solar cell 210 and the second solar cell 220.

Moreover, in addition to making adjustment for the current or voltage converted by the first solar cell 210 and the second solar cell 220 from the light beam L1, for being utilized by the subsequent electronic devices connected to this cell module 200, the junction box 230 also has the function of storing the electric energy thus obtained for future utilization.

In the present embodiment, a gap S1 can be kept between the first solar cell 210 and the second solar cell 220, namely, the first solar cell 210 and the second solar cell 220 are not placed closely together, as shown in FIG. 2. In another embodiment not shown, the first solar cell 210 and the second solar cell 220 are placed closely together. In other words, in a modularized cell module 200, whether the first solar cell 210 and the second solar cell 220 are placed together depends on actual requirements.

It has to be mentioned that, the first solar cells 110 and 210, and the second solar cells 120 and 220 mentioned above can all be thin film solar cells.

Summing up the above, the present invention has the following advantages: the first solar cell is located over the second solar cell, such that the first solar cell is able to absorb green light, blue light, and ultraviolet light of the sunlight, and allow most of the red light, orange light, yellow light, and infrared light to pass through. As such, in addition to raising the photoelectric conversion efficiency of the entire cell module, it can also avoid the possibility of the second solar cell being irradiated by the ultraviolet light, hereby increasing the service life of the second solar cell. In addition, since the first solar cell is placed over the second solar cell, thus it can protect the second solar cell from outside damage, such as hailstone.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A cell module, comprising:
a first solar cell, capable of absorbing green light, blue light, and ultraviolet light and converting them into electrical energy, and allowing red light, orange light, yellow light, and infrared light to pass through;
a second solar cell, located below said first solar cell, and is shielded by said first solar cell, and is combined with said first solar cell into said cell module, such that said second solar cell absorbs said red light, said orange light, said yellow light, and said infrared light passing through said first solar cell, and converting them into electrical energy.

2. The cell module as claimed in claim 1, wherein said first solar cell is a transparent solar cell.

3. The cell module as claimed in claim 1, wherein said second solar cell includes: an organic solar cell, a dye solar cell, a GaAs solar cell, or a CdTe solar cell.

4. The cell module as claimed in claim 1, wherein a gap exists between said first solar cell and said second solar cell.

5. The cell module as claimed in claim 1, wherein said first solar cell and said second solar cell are placed closely together.

6. The cell module as claimed in claim 1, wherein said first solar cell and said second solar cell are connected electrically in series or in parallel.

7. The cell module as claimed in claim 1, further comprising: a junction box, said first solar cell and said second solar cell are connected electrically through said junction box.

8. The cell module as claimed in claim 1, further comprising: a housing, said first solar cell and said second solar cell are placed in said housing, and said second solar cell is located between a bottom portion of said housing and said first solar cell.

9. The cell module as claimed in claim 8, wherein said housing is a transparent housing.

10. The cell module as claimed in claim 1, wherein said first solar cell and said second solar cell are both thin film solar cells.
